(19) United States
(12) Patent Application Publication
(10) Pub. No.: US 2026/0164726 A1
(43) Pub. Date: Jun. 11, 2026

(54) LATERAL POWER SEMICONDUCTOR DEVICE HAVING A VERTICAL CHANNEL AND METHODS FOR MAKING THE SAME

(71) Applicant: Microchip Technology Incorporated, Chandler, AZ (US)

(72) Inventors: Shesh Mani Pandey, Gilbert, AZ (US); Yogesh Kumar Sharma, Colorado Springs, CO (US)

(73) Assignee: Microchip Technology Incorporated, Chandler, AZ (US)

(21) Appl. No.: 19/393,346

(22) Filed: Nov. 18, 2025

Related U.S. Application Data
(60) Provisional application No. 63/730,279, filed on Dec. 10, 2024.

(51) Int. Cl. H10D 30/83; H10D 30/01; H10D 62/10; H10D 62/17

(52) U.S. Cl. CPC H10D 30/83; H10D 30/0512; H10D 62/116; H10D 62/328; H10D 62/343

(57) ABSTRACT

A lateral junction field-effect transistor including a volume of semiconductor material including a first end, a second end spaced vertically from the first end, a first side, and a second side spaced laterally from the first side. A source and a drain are located at the first end of the volume of semiconductor material. Laterally spaced apart first and second gates are also located at the first end of the volume of semiconductor material. The source is positioned between the first and second gates.

### RELATED APPLICATION

The present U.S. non-provisional patent application is related to and claims priority benefit of an earlier-filed U.S. provisional patent application titled “LATERAL POWER SEMICONDUCTOR DEVICE HAVING A VERTICAL CHANNEL AND METHODS FOR MAKING THE SAME,” Ser. No. 63/730,279, filed Dec. 10, 2024. The entire content of the identified earlier-filed application is incorporated by reference as if fully set forth herein.

### FIELD

The present disclosure relates to vertical channel lateral power semiconductor devices and methods of making them. More particularly, various examples of the present disclosure relate to a lateral junction field-effect transistor (JFET) having a vertical channel and methods for making the same.

### BACKGROUND

A JFET is an active, voltage-controlled semiconductor device, in which varying an electrical voltage between a gate and a body controls an electrical current flowing through a semiconductor channel between a drain and a source. Applications for JFETs include, but are not limited to, amplifiers (e.g., cascade and differential), switches, oscillatory circuitry, voltage-controlled resistors, and constant current sources. It is generally desirable to improve the performance and reduce the cost of JFETs, but it can be difficult to do so.

This background discussion is intended to provide related information, and is not necessarily prior art.

### SUMMARY

Broadly, a lateral semiconductor device is a semiconductor device in which the primary current flows horizontally (or laterally) through a channel that runs parallel to the surface of the device, rather than vertically through a channel that runs perpendicular to the surface of the device. This lateral current flow can be achieved by providing a drain of the semiconductor device on the same end of the volume of semiconductor material in which the semiconductor device is formed as a source of the semiconductor device.

Examples physically and functionally integrate a vertical channel (or channel portion(s)) into a lateral power semiconductor device. For instance, placing a source between two gates (or two sides of the same gate) of a lateral semiconductor device may introduce a vertical segment to the otherwise lateral channel of the semiconductor device. Introducing a vertical segment to what would otherwise be a lateral channel device provides an additional axis of control for shaping the channel of the device. A tighter/more restrictive channel may result in charge carriers traveling from source to drain in less time, thereby enhancing the performance of the device.

In various examples, the lateral power semiconductor device having a vertical channel (or channel portion(s)) may be a lateral junction field-effect transistor (or “JFET”). The lateral JFET having a vertical channel (or channel portion(s)) (or simply “the lateral JFET”) may include a volume of semiconductor material having a first end, a second end spaced vertically from the first end, a first side, and a second side spaced laterally from the first side. A source and a drain may be located at the first end of the volume of semiconductor material. First and second gates may also be located at the first end of the volume of semiconductor material. The first and second gates may be laterally spaced apart from each other, and the source may be located or positioned between the first and second gates.

The preceding example may include any one or more of the following features.

The first and second gates may be spaced laterally from the drain with the first gate being further from the drain than the second gate.

The lateral spacing between the second gate and the drain may be greater than the lateral spacing between the first and second gates.

The source, the first and second gates, and/or the drain may be provided via ion implantation.

The lateral JFET may comprise a trench that is defined in the first end of the volume of semiconductor material. The trench may be located/positioned between the second gate and the drain. The trench, which may be a shallow trench, e.g., as commonly used in shallow trench isolation (or “STI”) techniques for providing further electrical isolation between adjacent electrical components (in this case the second gate and the drain) may be formed by etching. An insulator, such as an oxide material, may be located inside the trench. The insulator may be formed by thermal oxidation, epitaxially grown, or otherwise provided within the trench.

The volume of semiconductor material may comprise a first sub-volume at the first end of semiconductor material and a second sub-volume vertically spaced from the first end of the volume of semiconductor material. The first and second sub-volumes of material may cooperatively define a sub-volume interface.

The first and second sub-volumes of semiconductor material may be epitaxially grown.

The lateral JFET may comprise a channel. The channel may include a first channel portion extending in a vertical direction between the first and second gates and a second channel portion extending from the first channel portion in a lateral direction toward the drain. The channel may include a third channel portion that extends from the second channel portion in a vertical direction to the drain.

The second channel portion may be located above and extend along the sub-volume interface.

A substrate may be provided/located at the second end of the volume of semiconductor material.

The first and second gates may be or at least partially comprise a P+ material. Each of the source, the drain, and the substrate may be or at least partially comprise an N+ material. The first sub-volume of semiconductor material may be or at least partially comprise an N-type material and the second sub-volume of semiconductor material may be or at least partially comprise a P-type material.

The channel of the lateral JFET may be configurable based on one or more of: a vertical depth of the first gate, a lateral width of the first gate, a vertical depth of the second gate, a lateral width of the second gate, a vertical depth of the trench, a lateral width of the trench, a vertical depth of one or more of the sub-volumes of the volume of semiconductor material, a lateral width of one or more of the sub-volumes of semiconductor material, a material composition of the first gate, a material composition of the second gate, a material composition of the trench, and a material composition of one or more of the sub-volumes of the volume of semiconductor material.

The vertical depth of the first and second gates may be equal.

The vertical depth and/or lateral width and material composition of each of the sub-components of the lateral JFET (e.g., the source, the drain, the first/second gates, the substrate, the trench, and the first/second sub-volumes of semiconductor material) may be varied so that the lateral JFET can achieve an array of specifications to suit various needs/use cases. For instance, while it may be preferable for the first and second gates to have the same material composition and dimensions, it may be preferable for the second gate to be shallower and/or narrower than the first gate in others.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional view of an example lateral junction field-effect transistor having a primarily lateral channel with one or more vertical channel segments;

FIG. 2 is a method flow for manufacturing the lateral junction field-effect transistor of FIG. 1; and

FIG. 3 is an alternative embodiment of the lateral junction field-effect transistor of FIG. 1, both having different dimensions of various sub-components when compared to FIG. 1 and illustrating various, additional ways in which the dimensions/geometry of various sub-components included therein can be modified within the scope of the present disclosure.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

The following description may include examples to help enable one of ordinary skill in the art to practice the disclosed examples. The use of terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Furthermore, the use of the term “vertical” herein is to be understood as generally defining a direction between the first and second ends of the volume of semiconductor material. For example, with respect to the “vertical” channel/channel segment, it should be understood that such portion/segment of the channel extends at least primarily in the vertical direction (e.g., in an orthogonal direction relative to the first end of the volume of semiconductor material, even if true orthogonality is not maintained over the entire span of the channel/channel segment). Similarly, the use of the term “lateral” herein is to be understood to as generally defining a direction between the first and second sides of the volume of semiconductor material. For example, a “lateral” channel/channel segment will be understood to be a portion/segment of a channel extending at least primarily in the horizontal direction (e.g., in a parallel direction relative to the first end of the volume of semiconductor material, even if true parallelism is not maintained over the entire span the channel/channel segment).

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

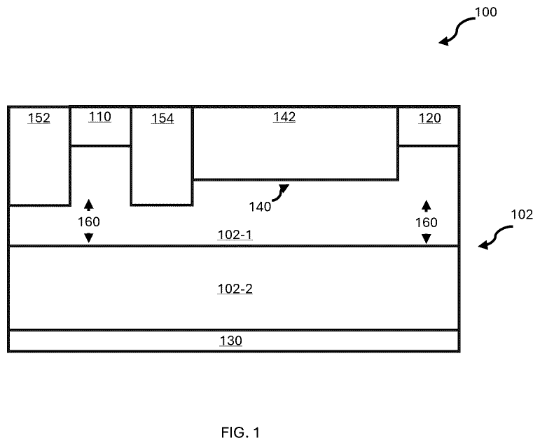

Referring to FIG. 1, an example of a lateral JFET 100 having one or more vertical channel segments is shown. According to various examples of the present disclosure, the lateral JFET 100 may be a silicon carbide (SiC) JFET. The improved reverse conduction (i.e., the third quadrant performance) of a SiC JFET is desirable for next-generation, compact power electronic devices.

The lateral JFET 100 includes a volume of semiconductor material 102 having a first end, a second end spaced vertically from the first end, a first side, and a second side spaced laterally from the first side. A substrate (such as the substrate 130) may be located/provided at the second end of the volume of semiconductor material 102. Additional semiconductor material may be grown (e.g., via epitaxy) or otherwise provided on/above the substrate 130 to complete the volume of semiconductor material 102. The lateral JFET 100 further includes a source 110, a drain 120, a trench 140, and first and second gates 152, 154. Each of the source 110, the drain 120, the trench 140, and the first and second gates 154, 154 may be located/provided at the first end of the volume of semiconductor material 102.

A (conductive) channel 160, originating at the source 110 and ending at the drain 120, is also depicted in FIG. 1. The channel 160 may form within the lateral JFET 100 in response to a voltage being applied to the first and second gates 152, 154. The channel 160 may include a lateral portion/segment in addition to one or more vertical portions/segments.

As illustrated in FIG. 1, the volume of semiconductor material 102 further includes a first sub-volume 102-1 of semiconductor material and a second sub-volume 102-2 of semiconductor material. The first sub-volume 102-1 may be located at the first end of the volume of semiconductor material 102. The second sub-volume 102-2 may be vertically spaced from the first end of the volume of semiconductor material 102 and adjacent the substrate 130. The first and second sub-volumes 102-1, 102-2 may cooperatively define a sub-volume interface. In various examples, the sub-volume interface may be a P-N junction formed at the boundary of the first and second sub-volumes 102-1, 102-2, e.g., when the first sub-volume 102-1 comprises an N-type material and the second sub-volume 102-2 comprises a P-type material.

As depicted in FIG. 1, each of the source 110, the drain 120, the trench 140, and the first and second gates 152, 154 are located at the first end of the volume of semiconductor material 102, and the substrate 130 is located at the second end of the volume of semiconductor material 102. Further, the source 110 is located between the first and second gates 152, 154, which are laterally spaced apart from each other. The drain 120 may be spaced laterally apart from the second gate 154. The lateral distance between the second gate 154 and the drain 120 may be greater than the lateral distance between the first and second gates 152, 154. The first gate 152 may be located at or near the first side of the volume of semiconductor material 102, and the drain 120 may be located at or near the second side of the volume of semiconductor material 102. The trench 140, which occupies at least a portion of the (lateral) space between the second gate 154 and the drain 120, is located at the first end of the volume of semiconductor material 102. It will be appreciated, according to some aspects of the disclosed examples, for the trench to be alternatively configured or configured or eliminated altogether.

According to various examples of the present disclosure, each of the source 110, the drain 120, and the first and second gates 152, 154 may be implanted, e.g., via ion implantation. The source 110 and the drain 120 may each be, or at least partially comprise, an N+ material. Each of the first and second gates 152, 154 may be, or at least partially comprise, a P+ material. The substrate 130 may be epitaxially grown and may be an N+ material. The trench 140, which may be a shallow trench, e.g., as commonly used in STI techniques for providing further electrical isolation between adjacent electrical components (e.g., the second gate 154 and the drain 120) may be formed by etching. An insulator 142, such as an oxide material, may be provided in the trench 140. The insulator 142 may at least partially fill the trench, and the insulator 142 may be formed by thermal oxidation, grown via epitaxy, or otherwise provided.

According to various examples of the present disclosure, each of the first and second gates 152, 154 may include an electrical (e.g., metal) contact (not depicted in FIG. 1), deposited, or otherwise provided, on top of the first end of the volume of semiconductor material. The electrical contacts provided on each of the first gate 152 and the second gate 154 may be shorted; however, according to certain aspects of the example JFET 100, the electrical contacts for the gates 152, 154 may alternatively be electrically isolated from each other.

Referring to FIG. 1, the channel 160 includes a first portion/segment extending in a vertical direction from the source 110 through the first sub-volume 102-1 and toward the sub-volume interface. Generally, channels of semiconductor devices, such as MOSFETs, JFETs, and the like, allow majority charge carriers to flow from source (e.g., the source 110) to drain (e.g., the drain 120) in response to a voltage being applied to a gate of the device (e.g., the first and second gates 152, 154), which may result in an electric current flowing through the device (e.g., from source to drain). Typically, a channel within a semiconductor device is a vertical channel, meaning majority charge carriers/current flows from the source at the “top” of the device (e.g., the first side of the volume of semiconductor material 102) down toward, and eventually into a drain (e.g., a metal contact deposited or otherwise provided on at least a portion of the substrate of the device, e.g., the substrate 130) located at the “bottom” (e.g., the second side of the volume of semiconductor material 102) of the device when a forward bias is applied to the device. It is common for there to only be one sub-volume of semiconductor material included in devices with vertical channels to have a single polarity (although the dopant concentration may gradually decrease from the top to the bottom), such as an N-type material.

However, because the source 110 and drain 120 of the lateral JFET 100 are each located on the “top side” of the device (e.g., the first end of the volume of semiconductor 102 comprising the lateral JFET 100), the channel consequently includes a horizontal, or lateral, segment. According to various examples of the present disclosure, the lateral segment of the channel 160 may represent the majority of the distance majority charge carriers must traverse in order to reach the drain 120 from the source 110.

The P-N junction that exists at the sub-volume interface as the result of the first and second sub-volumes 102-1, 102-2 having opposite polarity inhibits vertical flow of charge carriers into the second sub-volume 102-2 so as to facilitate “turning” of the channel 160, which is vertical at its origin between the first and second gates 152,154, laterally. This lateral turn routes charge carrier (e.g., current) flow to a direction that is (at least primarily) horizontal over a span. This P-N junction may not only facilitate shaping of the second, lateral portion/segment of the channel 160 (not depicted), but may also serve to reduce (if not effectively eliminate) any negative impacts of drift, diffusion, material impurities/imperfections, etc. that may arise under ordinary operating conditions and/or resulting from the ordinary manufacture of the lateral JFET 100. After extending for a distance (at least primarily) laterally, the channel 160 may turn, once again, (at least primarily) in a vertical direction before terminating at the drain 120. It will be appreciated by those of ordinary skill in the art that the third portion, which is vertical in the illustrated example to extend up to the drain 120 located at the first end of the volume of semiconductor material 102, may be eliminated in certain examples of the JFET. For instance, if the drain is alternatively located (or extends) below the first end of the semiconductor material (or the semiconductor material is shaped to position the drain downwardly relative to the position shown in FIG. 1), the alternatively shaped channel may simply extend horizontally from the first, vertical section to the drain.

Restricting/shaping the lateral portion/segment of the channel 160 may reduce the time it takes for current to travel from the source 110 to the drain 120, thereby enhancing performance of the lateral JFET 100. Other ways to restrict/shape at least a portion of the channel 160 of the lateral JFET 100 include, but are not limited to, modifying one or more of: the dimensions (e.g., a lateral width and/or a vertical depth) of either or both of the first and second gates 152, 154; the dimensions of the source 110; the dimensions of the drain 120; the dimensions of the trench 140; the dimensions of either or both of the first and second sub-volumes 102-1, 102-2; and the material composition/dopant concentrations of the materials comprising/filling the sub-components of the lateral JFET 100 mentioned above.

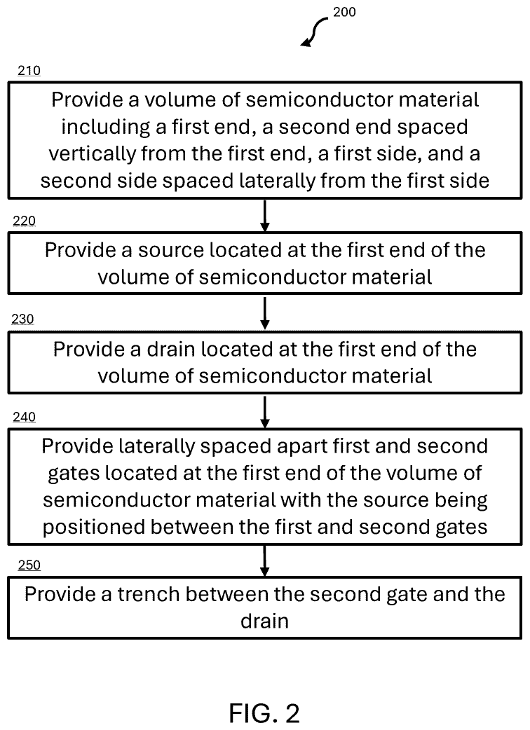

FIG. 2 depicts a method flow describing a method 200 for producing the lateral JFET 100 of FIG. 1. Unless expressly stated otherwise herein or as may be understood by those of ordinary skill in the art, the steps may be performed in the order shown in FIG. 2, or they may be performed in a different order. Furthermore, some steps may be performed concurrently as opposed to sequentially. In addition, some steps may be optional.

The method 200 includes providing, at operation 210, a volume of semiconductor material (e.g., the volume of semiconductor material 102 of FIG. 1) including a first end, a second end spaced vertically from the first end, a first side, and a second side spaced laterally (or horizontally) from the first side. The volume of semiconductor material may be epitaxially grown or otherwise provided on a substrate, such as the substrate 130 of FIG. 1. The substrate on which the volume of semiconductor material is grown may also be grown via epitaxy or otherwise provided. Referring to FIG. 1, because semiconductors grown via epitaxy are formed from the substrate up, the second sub-volume 102-1 of semiconductor is grown or otherwise provided before the first sub-volume 102-1 of semiconductor material.

At operations 220, 230, and 240, a source (e.g., the source 110), a drain (e.g., the drain 120), and a first and second gates (e.g., the first and second gates 152, 154) are provided, respectively. Each of the source, the gates, and the first and second gates may be provided on the same end (e.g., the first end) of the volume of semiconductor material. Each of the source, drain, and first and second gates may be provided via ion implantation. A semiconductor device having a source and a drain located/provided at the same end of the volume of semiconductor material in which the semiconductor device is formed may be considered a lateral semiconductor device (e.g., the lateral JFET 100). The first and second gates may be laterally spaced apart from each other such that the source may be located therebetween.

Further, the first gate may be provided at/near the first side of the volume of semiconductor materials and the drain may be provided at/near the second side of the volume of semiconductor material. The lateral distance between the second gate and the drain may exceed the lateral distance between the first gate and the second gate.

At operation 240, a trench (e.g., the trench 140) is provided. The trench may be provided via etching, and may be a shallow trench. Generally, shallow trenches provide further electrical isolation between adjacent sub-components of a semiconductor device (e.g., between the second gate 154 and the drain 120 of the lateral JFET 100 of FIG. 1).

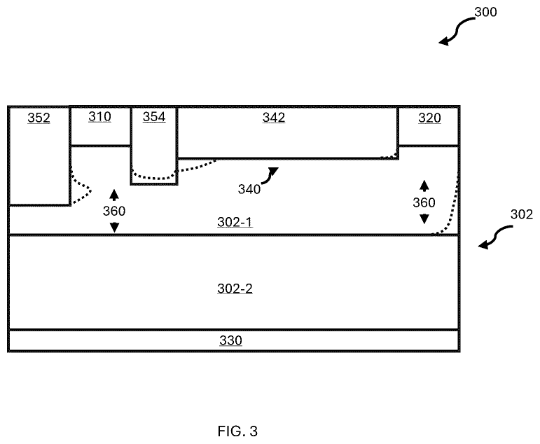

FIG. 3 illustrates an alternative lateral JFET 300 than depicted in FIG. 1, with the dimensions of some of the sub-components having been modified relative to the lateral JFET 100. More specifically, the second gate 354 depicted in FIG. 3 has a reduced vertical depth and a reduced lateral width when compared to the second gate 154 in FIG. 1. Further, the trench 340 in FIG. 3 has a reduced vertical depth and an increased lateral width when compared to the trench 140 of FIG. 1. Finally, the second sub-volume 302-2 of semiconductor material of the lateral JFET 300 is taller (e.g., of a greater vertical depth) than the second sub-volume 102-2 of semiconductor material of the lateral JFET 100, which in turn makes the first sub-volume 302-1 of semiconductor material of the lateral JFET 300 shorter (or of a lesser vertical depth) than the first sub-volume 102-1 of semiconductor material of the lateral JFET 100.

The above-described changes to the dimensions of the second gate 354 and the trench 340 may also serve to re-shape the channel 360 (e.g., when compared to the channel 160 of FIG. 1) in a manner that allows charge carriers (or current) traversing therethrough to reach the drain 320 more quickly, which may result in increased performance of the lateral JFET 300 when compared to the performance of lateral JFET 100. It is further noted that the various modifications of the JFET 300 relative to the JFET 100 need not all be implemented, but rather just one or some (but less than all) may be incorporated into an alternative JFET without departing from the scope of certain aspects of the disclosure. Furthermore, as noted below, additional (or less or more significant) alterations than shown in FIG. 3 may be implemented according to certain aspects of the of the disclosure.

More particularly, other arrangements/configuration of the volume of semiconductor material 302 are within the scope of certain aspects of the present disclosure. For instance, the inclusion of more or fewer sub-volumes of semiconductor material, sub-volume(s) of semiconductor material having different material compositions/concentrations and/or different dimensions (e.g., having a different vertical depth and/or lateral width) than those described above fall within the ambit of the present disclosure.

Further, other spacing and configurations/arrangements of the source 310, the drain 320, the trench 340, and the first and second gates 352, 354 are also within the scope of the present disclosure.

It will also be understood that each of the source 310, the drain 320, the trench 340, and the first and second gates 352, 354 having different material compositions/dopant concentrations and/or physical dimensions are contemplated by the disclosure. For instance, the dotted/dashed lines illustrated in FIG. 3 are meant to portray just a few of the theoretically infinite geometries of the various sub-components/sub-volumes of the lateral JFET 300 that may be within certain aspects of the present disclosure. Particularly noteworthy are: (i) the possibilities for asymmetry between the first and second gates 352, 354, and (ii) the extreme degree of control over shaping the channel 360 that may be encompassed with various aspects of the example JFET.

Various other means for providing each of the sub-components of the lateral JFET 300 are also within the scope of the present disclosure.

Although described herein with regard or in relation to one or more particular kinds of electronic devices (e.g., metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, unless otherwise specified or unless one with ordinary skill in the art would understand otherwise, the gate material may include polysilicon, a metal or alloy of metals, or other suitable material; and the semiconductor material may include silicon carbide, silicon, gallium nitride, zinc oxide, or other suitable material.

It will be appreciated that the sides of the illustrated volume of semiconductor material are defined herein merely as an example, and may in various examples represent only a portion of semiconductor material relative to the illustrated device. In practice, the volume of semiconductor material may extend laterally (leftward and rightward when viewing FIG. 1 or 3) beyond the bounds illustrated in the drawings to present additional semiconductor material in which additional devices may be provided. (The semiconductor material may similarly extend inwardly or outwardly (relative to the lateral or cross-sectional direction depicted in FIG. 1 or 3) to present additional devices in a direction transverse to the lateral direction.) Such additional devices may be FETs (which may be similarly or alternatively constructed to the illustrated JFET 100 or 300) or may be entirely different devices providing different operations or functions than the illustrated FFET 100 or 300. In other words, in practice, the illustrated JFET 100 or 300 may be just one of numerous devices spaced laterally and transversely within a single, integrally formed component, such as a wafer or integrated circuit (not shown).

Additionally, in general, unless otherwise specified or unless one with ordinary skill in the art would understand otherwise, doping concentrations for contact implants may be approximately between ten to the power of eighteen (10\hat{ }18) and ten to the power of twenty two (10\hat{ }22); doping concentrations for channel and threshold forming implants may be approximately between ten to the power of sixteen (10\hat{ }16) and ten to the power of seventeen (10\hat{ }17); doping concentrations for shielding implants may be approximately between ten to the power of seventeen (10\hat{ }17) and ten to the power of nineteen (10\hat{ }19); and doping concentrations for conductivity improvement implants (e.g., N-doping in the junction field-effect transistor neck region of a metal oxide semiconductor field-effect transistor) may be approximately between ten to the power of sixteen (10\hat{ }16) and ten to the power of seventeen (10\hat{ }17). Relatedly, a structure or region may contain two or more different doping doses. For example, one with ordinary skill in the art will recognize that some P-wells may contain a lower dose P-well portion and a higher dose unclamped inductive switching portion.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A lateral junction field-effect transistor comprising:
a volume of semiconductor material including a first end, a second end spaced vertically from the first end, a first side, and a second side spaced laterally from the first side;
a source located at the first end of the volume of semiconductor material;
a drain located at the first end of the volume of semiconductor material; and
laterally spaced apart first and second gates located at the first end of the volume of semiconductor material, with the source being positioned between the first and second gates.

2. The lateral junction field-effect transistor of claim 1, wherein the source, the first and second gates, and the drain are provided via ion implantation.

3. The lateral junction field-effect transistor of claim 1, wherein the first and second gates are spaced laterally from the drain, and the first gate is spaced further from the drain than the second gate.

4. The lateral junction field-effect transistor of claim 3, wherein the lateral spacing between the second gate and the drain is greater than the lateral spacing between the first and second gates.

5. The lateral junction field-effect transistor of claim 3, wherein a trench is defined in the first end of the volume of semiconductor material between the second gate and the drain.

6. The lateral junction field-effect transistor of claim 5, further comprising:
an oxide layer located within the trench.

7. The lateral junction field-effect transistor of claim 6, further comprising:
a channel that includes a first channel portion extending in a vertical direction from the source between the first and second gates and a second channel portion extending from the first channel portion in a lateral direction toward the drain.

8. The lateral junction field-effect transistor of claim 7, said channel including a third channel portion that extends from the second channel portion in a vertical direction to the drain.

9. The lateral junction field-effect transistor of claim 7, wherein the volume of semiconductor material further comprises:
a first sub-volume at the first end of the volume of semiconductor material, and
a second sub-volume vertically spaced from the first end of the volume of semiconductor material, with the first and second sub-volumes cooperatively defining a sub-volume interface
said second channel portion being located above and extending along the sub-volume interface.

10. The lateral junction field-effect transistor of claim 9, further comprising:
a substrate located at the second end of the volume of semiconductor material.

11. The lateral junction field-effect transistor of claim 10, wherein:
the first and second gates comprise a P+ material,
the source comprises an N+ material,
the drain comprises an N+ material;
the first sub-volume of semiconductor material comprises an N-type material,
the second sub-volume of semiconductor material comprises a P-type material, and
the substrate comprises an N+ material.

12. The lateral junction field-effect transistor of claim 11, wherein the channel is configurable based on one or more of: a vertical depth of the first gate, a lateral width of the first gate, a vertical depth of the second gate, a lateral width of the second gate, a vertical depth of the trench, a lateral width of the trench, a vertical depth of one or more of the sub-volumes of the volume of semiconductor material, a lateral width of one or more of the sub-volumes of semiconductor material, a material composition of the first gate, a material composition of the second gate, a material composition of the trench, and a material composition of one or more of the sub-volumes of the volume of semiconductor material.

13. The later junction field-effect transistor of claim 5, wherein the trench is a shallow trench formed by etching.

14. The lateral junction field-effect transistor of claim 1, wherein the vertical depth of the first and second gates is equal.

15. The lateral junction field-effect transistor of claim 1, further comprising:
a channel that includes a first channel portion extending in a vertical direction from the source between the first and second gates and a second channel portion extending from the first channel portion in a lateral direction toward the drain.

16. The lateral junction field-effect transistor of claim 15,
said channel including a third channel portion that extends from the second channel portion in a vertical direction to the drain.

17. The lateral junction field-effect transistor of claim 16, wherein the volume of semiconductor material further comprises:
a first sub-volume at the first end of the volume of semiconductor material, and
a second sub-volume vertically spaced from the first end of the volume of semiconductor material, with the first and second sub-volumes cooperatively defining a sub-volume interface,
said second channel portion being located above and extending along the sub-volume interface.

18. The lateral junction field-effect transistor of claim 17, wherein the first sub-volume of semiconductor material comprises an N-type material, and the second sub-volume of semiconductor material comprises a P-type material.

19. The lateral junction field-effect transistor of claim 18, wherein the first and second sub-volumes of semiconductor material and the substrate are epitaxially grown.
